(19) United States
(12) Patent Application Publication
(10) Pub. No.: US 2008/0042553 A1
(43) Pub. Date: Feb. 21, 2008

(54) Low-Reflectance Self-Illumination Unit Display

(75) Inventor: Shi-Hao Li, Hsin-Chu (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: AU OPTRONICS CORPORATION, Hsin-Chu (TW)

(21) Appl. No.: 11/684,771

(22) Filed: Mar. 12, 2007

(30) Foreign Application Priority Data
Aug. 16, 2006 (TW) 95130103

(51) Int. Cl. H05B 33/00; H01L 51/50; H05B 33/06

(52) U.S. Cl. 313/501; 313/500; 313/506

(57) ABSTRACT

The present invention provides a self-illumination unit display comprising a display substrate, a light-absorbing structure, a driving circuit unit, a self-illumination unit and a light modulation layer. The light-absorbing structure, the driving circuit unit and the self-illumination unit are all formed on the inner surface side of the display substrate, while the light modulation layer is preferably formed on the outer surface of the display substrate. The light-absorbing structure is formed on the inner surface of the display substrate, and is substantially located within the non-light-emitting area. The driving circuit unit is located above the light-absorbing structure. The self-illumination unit is substantially located within the light-emitting area. The light modulation layer is disposed on the outer surface of the display substrate. The light transmittance of the light modulation layer is approximately greater than 42%.

### BACKGROUND

1. Field of the Invention

The present invention relates generally to a self-illumination unit display, and more particularly to a low-reflectance self-illumination unit display.

2. Description of the Prior Art

With the increasing demand for thin-type displays, the technology advancement of the self-illumination unit display becomes more and more important. The technology of self-illumination unit display including organic light emitting diode (OLED) display is getting mature as well. For example, for OLED display, the display panel brightness and contrast is usually the main consideration to evaluate the overall quality. Hence, in the display field for the time being, how to effectively enhance the utilization rate of light emitting out of the self-illumination unit has become a major goal.

With respect to the display contrast, the overall color and the image performance of the display panel is more desirable when the contrast is high. However, in contrast enhancement method, besides enhancing brightness of the self-illumination unit, how to block the reflection of ambient light is also a major concern. Since ambient light enters into the display panel from the display and reflects out of the display through electrode or transistor elements within the display panel, the reflecting light constantly affects the performance of light originally emitting out of the display panel and brings about the reduced contrast. Therefore, how to reduce the reflection of ambient light becomes a current challenge.

As shown in FIG. 1, in order to reduce the display panel reflectance, conventionally, a polarizer 30 is configured onto an outer surface 11 of a display panel substrate 10.

### SUMMARY OF THE INVENTION

One object of the present invention is to provide a self-illumination unit display having a lower ambient light reflectance.

Another object of the present invention is to provide a self-illumination unit display having a preferable contrast performance.

Still another object of the present invention is to provide a self-illumination unit display having a preferable utilization rate of the emitted light.

The self-illumination unit display comprises a display substrate, a light-absorbing structure, a driving circuit unit, a self-illumination unit and a light modulation layer. The light-absorbing structure, the driving circuit unit and the self-illumination unit are all formed on an inner surface side of the display substrate, while the light modulation layer is preferably formed on an outer surface side of the display substrate.

The light-absorbing structure is formed on the inner surface of the display substrate and is located in a non-light-emitting area. The driving circuit unit is located above the light-absorbing structure. The self-illumination unit is located on the inner surface side of the display substrate, and is substantially located within a light-emitting area. The light modulation layer is disposed on the outer surface of the display substrate. The light transmittance of the light modulation layer is approximately greater than 42%, and preferably ranges approximately between 42% and 80%.

The amount of ambient light getting into the non-light-emitting area of the display substrate can be reduced through disposing the light-absorbing structure, and thereby reduce the reflecting light caused by the driving circuit unit reflecting the ambient light. The configuration of the light modulation layer can reduce the amount of ambient light getting into the display substrate to enhance the contrast of image created by light emitting out of the self-illumination unit. Moreover, through the collocation of the light modulation layer and the light-absorbing structure, the amount of reflecting light generated by incident ambient light can be reduced effectively to achieve the effect of enhancing the display contrast.

### BRIEF DESCRIPTION OF THE DRAWINGS

FIG. 1 is a cross-sectional view of a traditional OLED (organic light emitting diode) display panel.

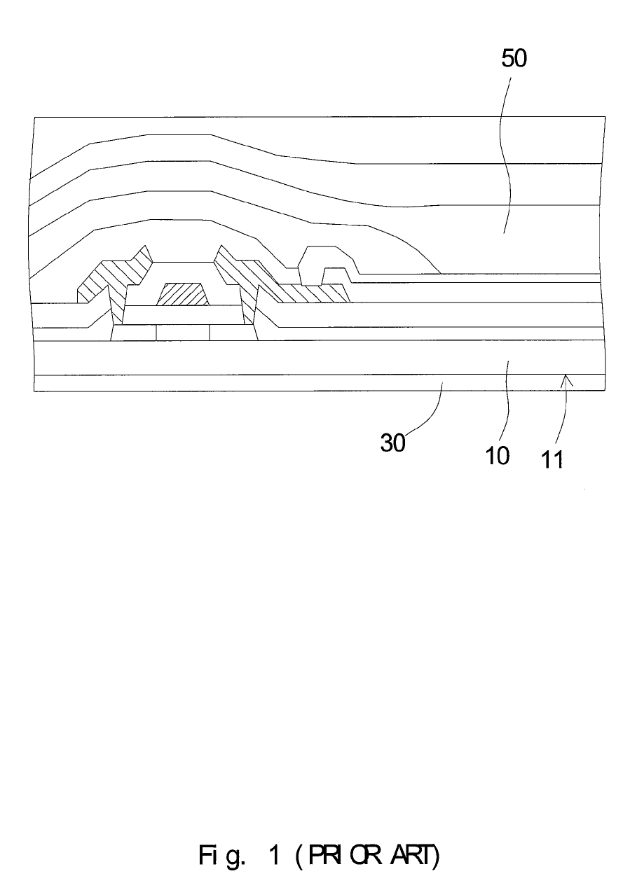

FIG. 2 is an exploded view of the self-illumination unit display in an embodiment of the present invention.

FIG. 3 is a cross-sectional view of the self-illumination unit display in one embodiment of the present invention.

FIG. 4 is a schematic diagram of the projection position of the self-illumination unit display in an embodiment of the present invention.

FIG. 5 is a schematic diagram of an OLED using a red light, a green light and a blue light in an embodiment of the present invention.

FIG. 6 is a schematic diagram of an OLED using a white light with color filters in one embodiment of the present invention.

FIG. 7 is a reflectance test diagram when using a polarizer having 57% light transmittance as the light modulation layer.

FIG. 8 is a cross-sectional view of the self-illumination unit display in another embodiment of the present invention.

### DETAILED DESCRIPTION OF THE PREFERRED EMBODIMENT

The present invention provides a self-illumination unit display. In the preferred embodiment, the self-illumination unit display of the present invention includes a color organic light emitting diode (OLED) display. However, in other embodiments, the self-illumination unit display of the present invention may be a monochromatic OLED display. In still other embodiments, the self-illumination unit display of the present invention may also include a high polymer OLED display. The self-illumination unit display of the present invention can be applied to various panel displays, household flat panel TV, flat panel monitor for desktop and laptop, and display screen for cellular phone and digital camera.

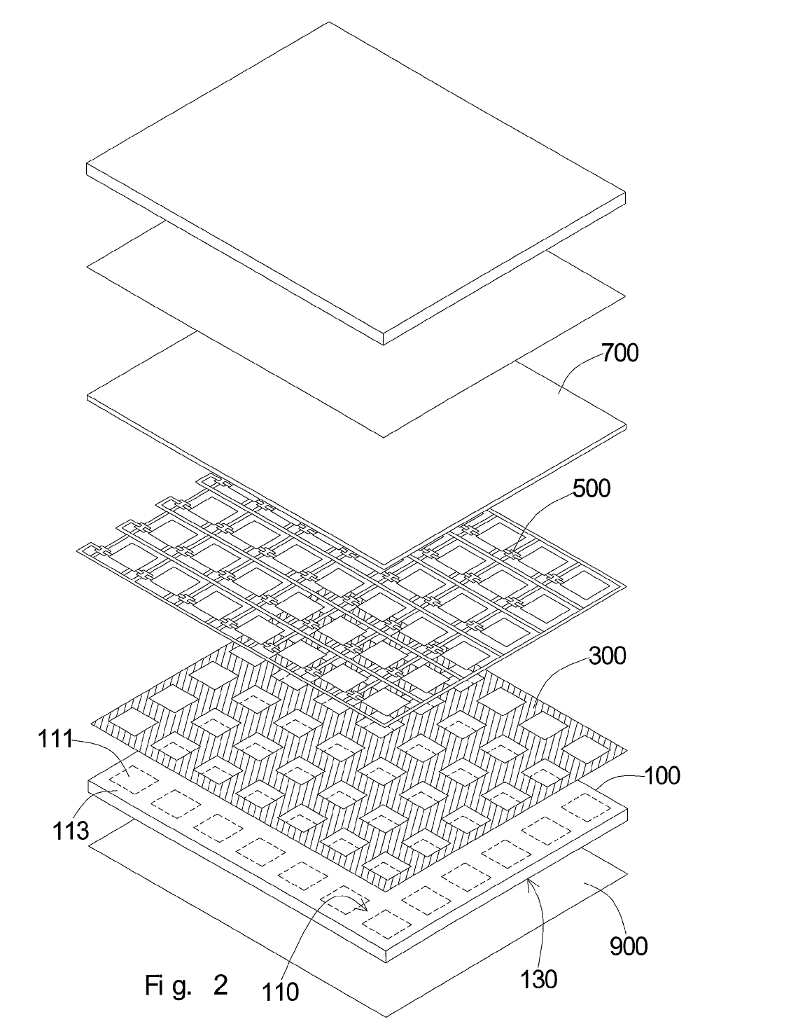

In the preferred embodiment shown in FIG. 2, the self-illumination unit display comprises a display substrate 100, a light-absorbing structure 300, a driving circuit unit 500, a self-illumination unit 700 and a light modulation layer 900. The display substrate 100 has an inner surface 110 and an outer surface 130. The light-absorbing structure 300, the driving circuit unit 500 and the self-illumination unit 700 are all formed on the inner surface 110 side of the display substrate 100, while the light modulation layer 900 is preferably formed on the outer surface 130 of the display substrate 100. The display substrate 100 is preferably made from transparent materials, such as glass, quartz, acrylic or organic materials containing polymers. Moreover, as shown in FIG. 2, the inner surface 110 of the display substrate 100 has a light-emitting area 111 and a non-light-emitting area 113.

The light-absorbing structure 300 is formed on the inner surface 110 of the display substrate 100, and is located within the non-light-emitting area 113. In the preferred embodiment, the light-absorbing structure 300 entirely covers the non-light-emitting area 113. However, in other embodiments, the light-absorbing structure 300 may only partially cover the non-light-emitting area 113. The amount of ambient light getting into the non-light-emitting area 113 of the display substrate 100 can be reduced through disposing the light-absorbing structure 300, and thereby reduce the reflecting light caused by the circuit or electronic device reflecting the ambient light. In the preferred embodiment, the light-absorbing structure 300 includes a black matrix whose composition includes single-layer organic film, single-layer inorganic film, compound organic film, compound inorganic film, or the combination thereof. In the preferred embodiment, the black matrix includes a chromium (Cr) black matrix. However, in other embodiments, the black matrix may include other kinds of black matrix, such as a resin black matrix and graphite black matrix.

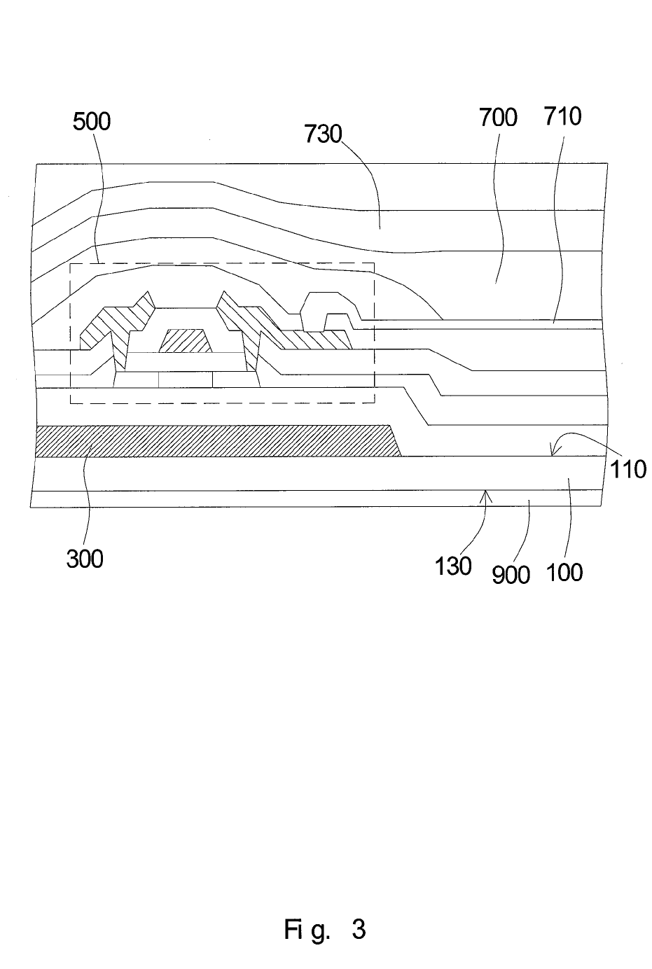

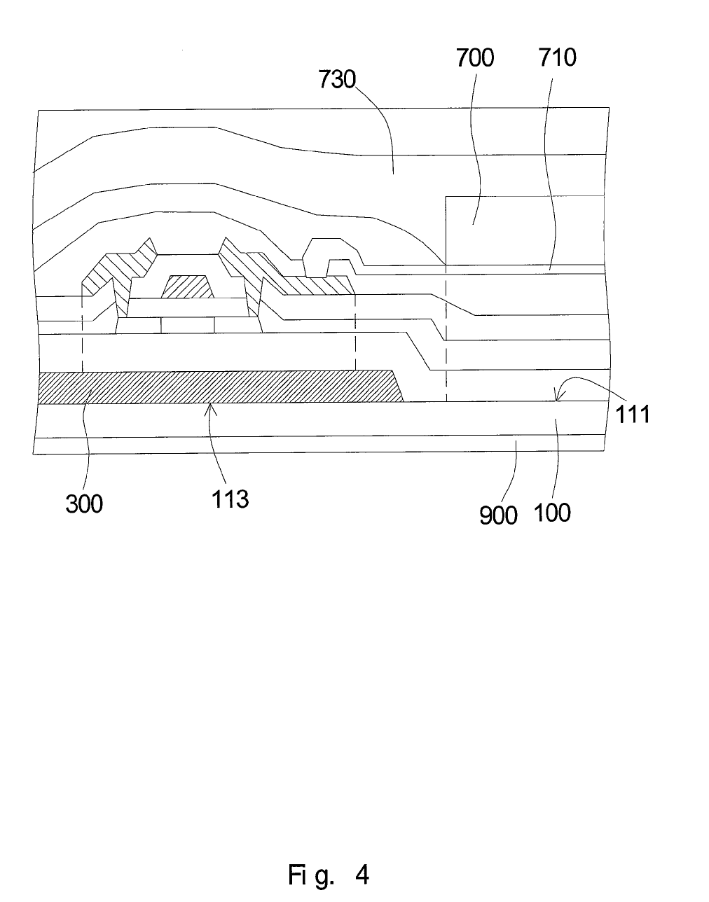

As shown in FIG. 3, the driving circuit unit 500 is located above the light-absorbing structure 300. For ambient light incident from the display substrate 100, the light-absorbing structure 300 can cover the driving circuit unit 500. Consequently, the driving circuit unit 500 will not get rayed easily by the ambient light, and further avoid the ambient light reflecting outside of the display substrate 100 through the driving circuit unit 500 or the metal materials thereof. The self-illumination unit 700 is sandwiched in between an electrode 710 and another electrode 730. Moreover, the self-illumination unit 700 can be extended-designed to overlap or not to overlap the driving circuit unit 500. In the preferred embodiment shown in FIG. 4, the light-absorbing structure 300 covers the vertical projection of the driving circuit unit 500 onto the inner surface 110 of the display substrate 100 and thereby achieves a preferable cover effect. The driving circuit unit 500 preferably includes a thin film transistor (TFT). However, in other embodiments, the driving circuit unit 500 may be other circuit type with similar functions, such as a metal-insulator-metal thin film diode (MIM-TFD) circuit. The TFT forming method preferably includes an amorphous silicon (a-Si) process, low temperature poly-silicon (LTPS) and other processes with similar effect.

As shown in FIG. 4, the self-illumination unit 700 is located on the inner surface 110 of the display substrate 100, and is substantially located within the light-emitting area 111. In other words, the light emitting out of the self-illumination unit 700 can travel outside the display substrate 100 through the light-emitting area 111. In the preferred embodiment, as shown in FIG. 4, the vertical projection of the self-illumination unit 700 onto the inner surface 110 of the display substrate 100 falls within the light-emitting area 111 of the inner surface 110. The self-illumination unit 700 preferably includes an organic light emitting diode (OLED); however, in other embodiments, the self-illumination unit 700 may include polymer OLED (P-OLED). In addition, the self-illumination unit 700 is connected with the driving circuit unit 500 through the electrode 710. The electrode 710 preferably includes an indium tin oxide (ITO) film; however, in other embodiments, the electrode 710 may include transparent or conductive film materials. The self-illumination unit 700 is sandwiched in between the electrode 710 and another electrode 730. Furthermore, the self-illumination unit 700 can be extended-designed to overlap or not to overlap the driving circuit unit 500.

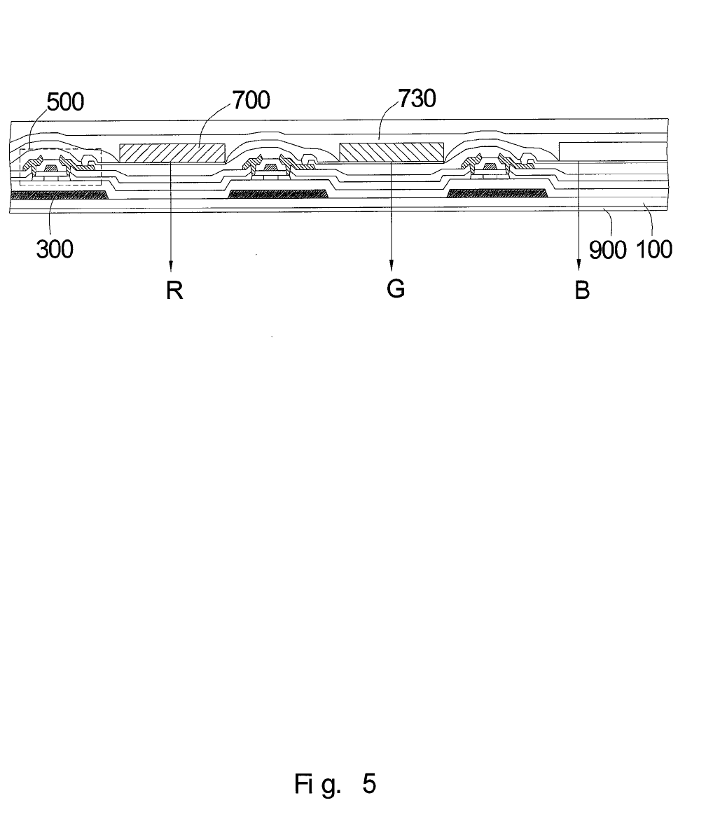

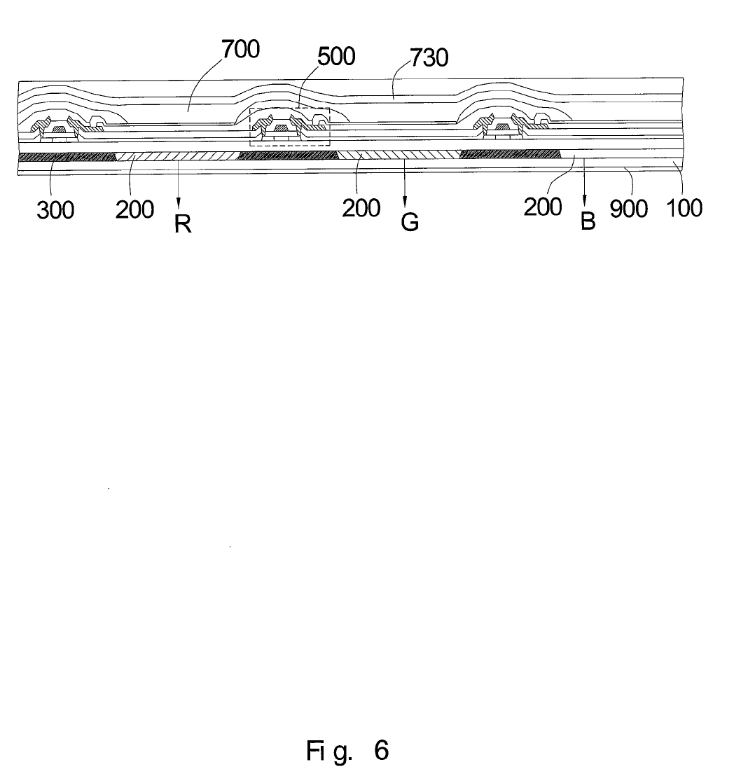

In the embodiment shown in FIG. 5, depending on different materials and blends, the self-illumination unit 700 includes red OLED, green OLED or blue OLED, i.e. one of the red, green or blue lights. Moreover, the three adjacent self-illumination units 700 provide red R, green G and blue B respectively to achieve color harmony, and to further provide full-color display effect. The electrode 730 corresponding to each of the R, G and B self-illumination unit 700 can be electrically connected to a voltage source (not shown) or another different voltage source (not shown). However, in the embodiment shown in FIG. 6, the self-illumination unit 700 is a white OLED, i.e. it provides white output light. As shown in FIG. 6, color filters 200 are formed on the light-emitting area 113 of the inner surface 110 of the display substrate 100. The white light emitting out of the self-illumination unit 700 produces red, green and blue light respectively through the color filters 200. In the preferred embodiment, the color filters 200 entirely cover the display substrate 100, and are adjacent to the light-absorbing structure 300.

As shown in FIG. 3, the light modulation layer 900 is disposed on the outer surface 130 of the display substrate 100. The light modulation layer 900 is preferably disposed on the outer surface 130 of the display substrate 100 by employing the method of adhesion; however, in other embodiments, the light modulation layer 900 may be formed directly on the outer surface 130 of the display substrate 100 by a thin film process. The aforementioned thin film processes include yellow light and etching process as well besides the methods of evaporation, deposition, sputtering and imprinting.

In the preferred embodiment, the light modulation layer 900 includes a polarizer. However, in other embodiments, the light modulation layer 900 may be a neutral density filter (ND filter), wavelength retardation plate, anti-glare film, other films or plates with light-diminishing functions or the combinations thereof. In the embodiment of the present invention, the light transmittance of the light modulation layer 900 is approximately greater than 42%. In the preferred embodiment, the light transmittance of the light modulation layer 900 is approximately between 42% and 80%. The light transmittance of the light modulation layer 900 may be further set between 42% and 57%, preferably between 42% and 44% to accord with the display properties and design requirement. In addition, the light reflectance of the light modulation layer 900 is preferably lower than 50%.

In the embodiment shown in FIG. 3, through driving of the driving circuit unit 500, the self-illumination unit 700 emits light which penetrates through the electrode 710, the display substrate 100 and the light modulation layer 900 connected with the driving circuit unit 500, and rays outward. The amount of ambient light getting into the display substrate 100 can be reduced through the blocking of the light modulation layer 900 to enhance the image contrast created by the light emitting out of the self-illumination unit 700. In addition, through the collocation of the light modulation layer 900 and the light-absorbing structure 300, the amount of reflecting light generated by incident ambient light can even be reduced effectively to achieve the effect of enhancing the display contrast. In the preferred embodiment, when the light transmittance of the light modulation layer 900 is approximately greater than 42%, the overall reflectance of the display can be reduced to under 20%.

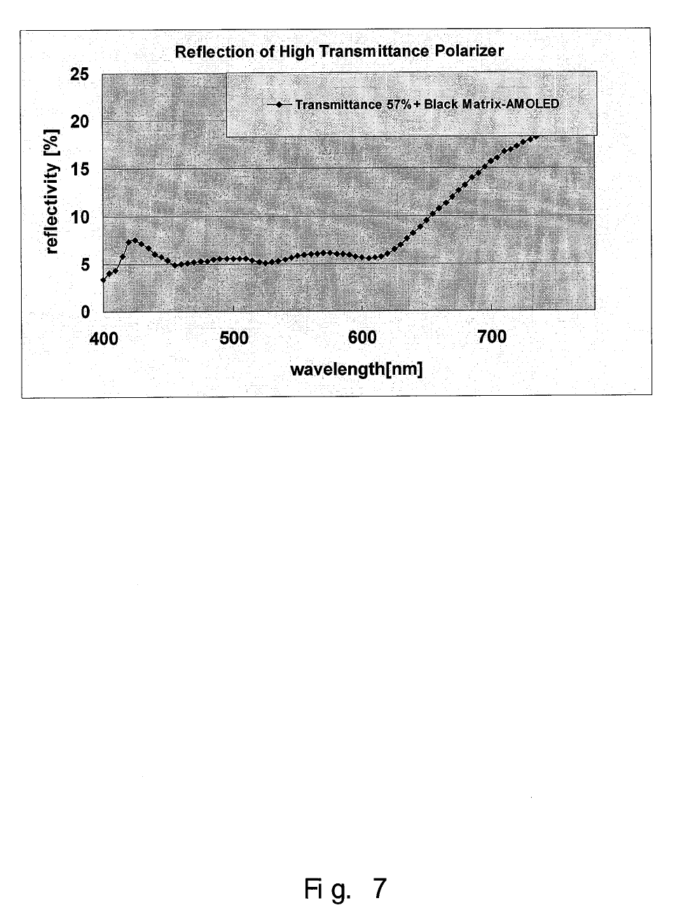

As shown in FIG. 7, the overall reflectance can be controlled within 10% under most circumstances when the display employs the polarizer having about 57% light transmittance as the light modulation layer 900 and works together with the light-absorbing structure. Furthermore, because used together with the light-absorbing structure 300, the overall reflectance can be reduced without using the light modulation layer 900 having over-low light transmittance, and thereby enhance the overall brightness and light utilization rate of the system.

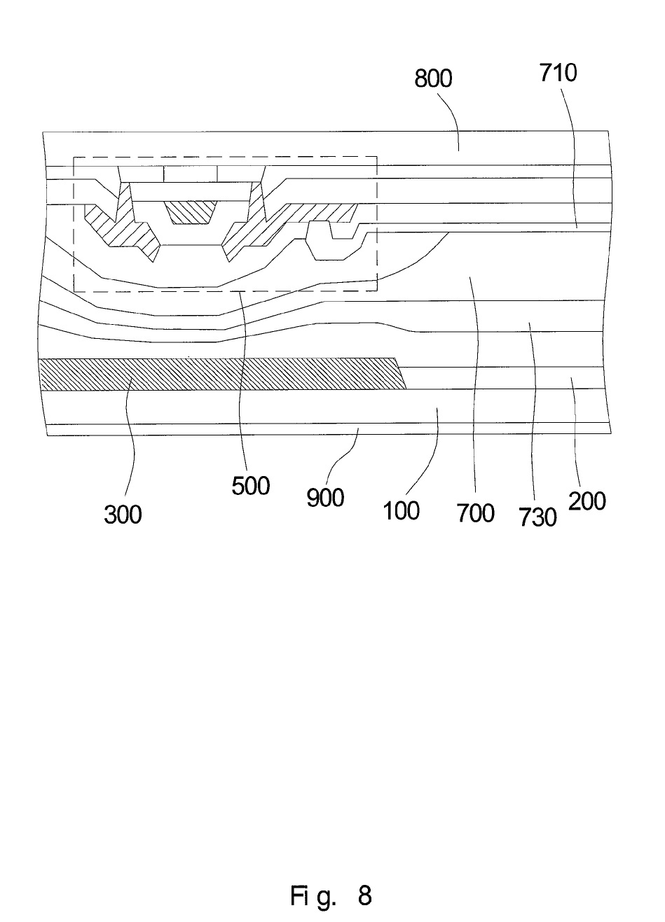

FIG. 8 shows a schematic diagram of another embodiment of the present invention. In this embodiment, the light generated by the self-illumination unit 700 does not pass through the electrode 710 connected with the driving circuit unit 500, but rays outward through the electrode 730, the color filters 200, the display substrate 100 and the light modulation layer 900 on another side. In this embodiment, the driving circuit unit 500 is formed on a backside substrate 800, and can still be located above the light-absorbing structure. In addition, the electrode 730 preferably includes indium tin oxide (ITO) thin films; however, in other embodiments, the electrode 730 may include transparent or conductive film materials. The self-illumination unit 700 is sandwiched in between the electrode 710 and the electrode 730. Moreover, the self-illumination unit 700 can be extended-designed to overlap (as shown in FIG. 8) or not to overlap the driving circuit unit 500.

From the foregoing, it shall be appreciated that specific embodiments of the invention have been described herein for purposes of illustration, but that various modifications and alterations may be made by those skilled in the art without deviating from the spirit and scope of the invention. Accordingly, the invention is not limited except as by the appended claims.

What is claimed is:

1. A self-illumination unit display comprising:
a display substrate having an inner surface and an outer surface, wherein said inner surface has a light-emitting area and a non-light-emitting area;
a light-absorbing structure formed on said inner surface of said display substrate and being located in said non-light-emitting area;
a driving circuit unit located above said light-absorbing structure, wherein said light-absorbing structure substantially covers said driving circuit unit;
a self-illumination unit located on said inner surface side of said display substrate and substantially located within said light-emitting area; wherein said self-illumination unit is electrically connected with said driving circuit unit; and
a light modulation layer disposed on said outer surface of said display substrate, wherein a light transmittance of said light modulation layer is approximately greater than 42%.

2. The self-illumination unit display of claim 1, wherein said light-absorbing structure includes a black matrix.

3. The self-illumination unit display of claim 1, wherein said light modulation layer includes a polarizer.

4. The self-illumination unit display of claim 1, wherein said light modulation layer includes a neutral density filter (ND filter).

5. The self-illumination unit display of claim 1, wherein said light modulation layer includes a wavelength retardation plate.

6. The self-illumination unit display of claim 1, wherein said light modulation layer includes an anti-glare film.

7. The self-illumination unit display of clam 1, wherein said light-absorbing structure entirely covers said non-light-emitting area of said inner surface.

8. The self-illumination unit display of claim 1, wherein said light transmittance of said light modulation layer is approximately smaller than 80%.

9. The self-illumination unit display of claim 1, wherein said light transmittance of said light modulation layer ranges approximately between 42% and 57%.

10. The self-illumination unit display of claim 1, wherein said self-illumination unit includes an organic light emitting diode (OLED).

11. The self-illumination unit display of claim 1, wherein said self-illumination unit includes a polymer organic light emitting diode (P-OLED).

12. The self-illumination unit display of claim 1, wherein said self-illumination unit provides a red light, a green light, or a blue light.

13. The self-illumination unit display of claim 1, wherein said self-illumination unit provides a white light.

14. The self-illumination unit display of claim 13 further comprising a color filter (CF) disposed on said display substrate.

15. The self-illumination unit display of claim 1 further comprising a color filter (CF) disposed on said display substrate.

16. The self-illumination unit display of claim 1, wherein said driving circuit unit includes a thin-film transistor (TFT).
